(19) United States
(12) Patent Application Publication
(10) Pub. No.: US 2012/0112611 A1
(43) Pub. Date: May 10, 2012

(54) SERVER CABINET STRUCTURE

(75) Inventors: Chien-An Chen, Taipei (TW); Kai-Yang Tung, Taipei (TW); Ming-Hung Shih, Taipei (TW); Chun-Ying Yang, Taipei (TW); Chung-Sheng Ni, Taipei (TW)

(73) Assignee: INVENTEC CORPORATION, Taipei (TW)

(21) Appl. No.: 13/158,628

(22) Filed: Jun. 13, 2011

(30) Foreign Application Priority Data
Nov. 5, 2010 (TW) 099138222

(51) Int. Cl. H05K 5/02

(52) U.S. Cl. 312/223.2

(57) ABSTRACT

A server cabinet structure includes a rack, at least one tray and at least one fixing component. The rack has two opposite frame bars and at least two guide rails correspondingly disposed on the frame bars. The tray is disposed on the two guide rails, and is capable of sliding into the rack. The guide rails are accommodated in recessed portions of the tray exactly. The tray presses against the frame bars through a stop plate. One combining hole of the stop plate is corresponding to an assembly hole of the frame bar. The fixing component passes through the combining hole and the assembly hole, and is inserted into the frame bar, so as to limit and keep the tray inside the rack.

### CROSS-REFERENCE TO RELATED APPLICATIONS

This non-provisional application claims priority under 35 U.S.C. §119(a) on Patent Application No(s). 099138222 filed in Taiwan, R.O.C. on Nov. 5, 2010, the entire contents of which are hereby incorporated by reference.

### BACKGROUND OF THE INVENTION

1. Field of the Invention

The present invention relates to a server cabinet, and more particularly to a server cabinet structure to and from which a tray can be loaded and unloaded quickly.

2. Related Art

With the development of science and technology, a computer device is expected to start and run various programs within a shortest period, so as to meet speed requirements of data processing from customers. Development objects of increasing processing speed and performing multiplex operation are achieved by increasing chip precision in the industry, so that server architecture consisting of multiple circuit boards and electronic components thereof is developed.

When multiple main boards are to be installed in an existing server rack, the multiple main boards are placed on provided trays. Additionally, the server rack is divided into multiple rooms, so that all of the trays loaded with the main boards are arranged in the rack at intervals. In addition, with multiple sets of slide rail structures inside the rack, the trays are inserted in the rack.

In order that the trays can be easily placed in the server firmly, multiple slide rail brackets and multiple slide rails matching each other are mounted on the rack of the server, so as to fix and retain the trays in the server rack. Specifically, each slide rail bracket has two shoulder portions and a mounting portion, and the slide rail bracket is fixed on the server rack by screwing screws into screw holes in the shoulder portions. Each slide rail includes a pair of outer slide rails mounted on the slide rail bracket and a pair of inner slide rails mounted on the server, and the server slides into the outer slide rails through the inner slide rails.

After the tray is pushed to a predetermined position in the server rack, the server and a fixing plate are combined to each other, and a thumb screw passes through the tray and the fixing plate and is screwed into a corresponding screw hole of the rack, so as to fix the tray inside the rack, thus ensuring an electrical connection between a main board in the tray and a power system of the server rack (connection in the form of electrical connectors).

High reliability and high extensibility are the most required for the main boards of the conventional server, and the main reason is that each main board has a hot swapping function, the main board can be directly electrically connected to an external electrical connection port through an electrical connector, and the main board of the server is required to be plugged in and pulled out frequently. Therefore, the fixation achieved by screwing the screw into the screw hole makes it inconvenient to plug in and pull out the main board of the server, and also leads to problems that the alignment of the screws is not easy, the screws are easily lost, and the thumb screw is expensive.

In addition, in order that the trays can be placed firmly in the rack and can slide relative to the rack, the conventional server rack must be mounted with multiple sets of slide rail brackets and slide rails for directly placing the trays thereon. Thus, the slide rail brackets and slide rails occupy too much room inside the server rack, which limits the usable room in the server rack. Therefore, the number of circuit boards that can be loaded in a single server rack is also limited, and installation of the maximum number of circuit boards cannot be achieved, so that the operation performance of the server cabinet cannot be improved.

### SUMMARY OF THE INVENTION

In view of the above problems, the present invention is a server cabinet structure, so as to solve the problems in the prior art that the fixation of the trays to the server rack by screws is rather inconvenient, making it inconvenient to plug in and pull out the main board of the server, and that the server rack cannot be loaded with the maximum number of circuit boards, because the slide rail brackets and slide rails occupy too much usable room in the server rack.

The server cabinet structure of the present invention comprises a rack, at least one tray and at least one fixing component. The rack has two opposite frame bars and at least two guide rails. Each of the frame bars is opened with a plurality of assembly holes. The two guide rails are respectively disposed on the frame bars, and the guide rails are arranged corresponding to each other. The tray is disposed on the two guide rails, and is capable of sliding into the rack through the guide rails. The tray has at least one stop plate and two recessed portions. The stop plate has at least one combining hole. The two recessed portions are respectively corresponding to the two guide rails. When the tray is located in the rack, the two guide rails are respectively accommodated in the two recessed portions, the stop plate presses against one of the frame bars, and the combining hole of the stop plate is corresponding to one of the assembly holes of the frame bar. The fixing component passes through the combining hole and at least one of the assembly holes, and is inserted into at least one of the frame bars, so as to limit and keep the tray inside the rack.

Beneficial effects of the present invention are as follows. The fixing component is fixed in the frame bar by insertion, so that the tray can be fixedly disposed into the rack or removed from the rack quickly and conveniently, which not only greatly simplifies the procedures for loading and unloading the tray, but also reduces the time required for the loading and unloading operations.

Additionally, the guide rails of the rack are completely accommodated in the recessed portions of the tray, and do not occupy any other usable room inside the rack, so that the rack can be loaded with the maximum number of circuit boards, and a single server cabinet can achieve the highest operation performance.

These and other aspects of the present invention will become apparent from the following description of the preferred embodiment taken in conjunction with the following drawings, although variations and modifications therein may be affected without departing from the spirit and scope of the novel concepts of the disclosure.

These and other aspects of the present invention will become apparent from the following description of the preferred embodiment taken in conjunction with the following drawings, although variations and modifications therein may be affected without departing from the spirit and scope of the novel concepts of the disclosure.

### BRIEF DESCRIPTION OF THE DRAWINGS

The accompanying drawings illustrate one or more embodiments of the invention and, together with the written description, serve to explain the principles of the invention. Wherever possible, the same reference numbers are used throughout the drawings to refer to the same or like elements of an embodiment, and wherein:

FIG. 1 is a schematic exploded view according to an embodiment of the present invention;

FIG. 2 is a schematic three-dimensional view according to an embodiment of the present invention;

FIG. 3A is a schematic exploded view of a tray and a circuit board according to an embodiment of the present invention;

FIG. 3B is a schematic three-dimensional view of a tray and a circuit board according to an embodiment of the present invention;

FIG. 4A is a schematic plane view according to an embodiment of the present invention;

FIG. 4B is a schematic partially enlarged exploded view according to an embodiment of the present invention; and

FIG. 4C is a schematic partially enlarged view according to an embodiment of the present invention.

### DETAILED DESCRIPTION OF THE INVENTION

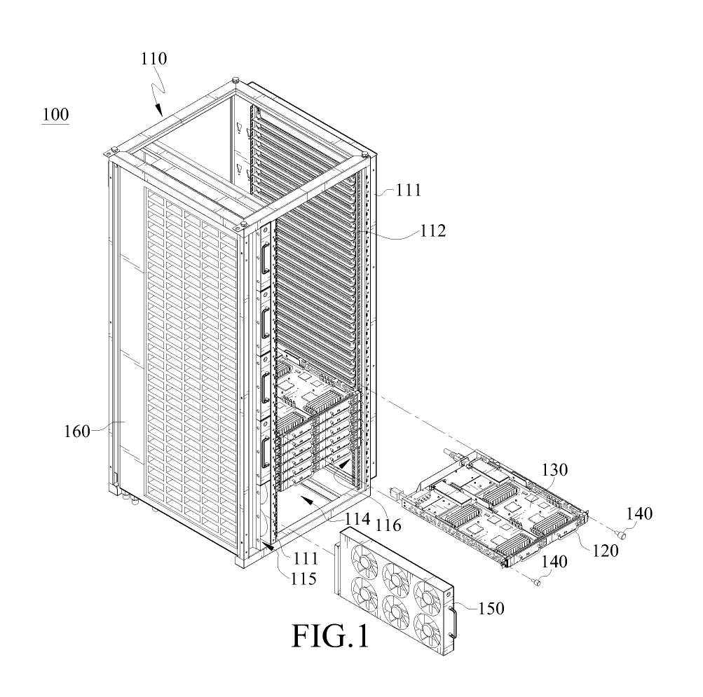

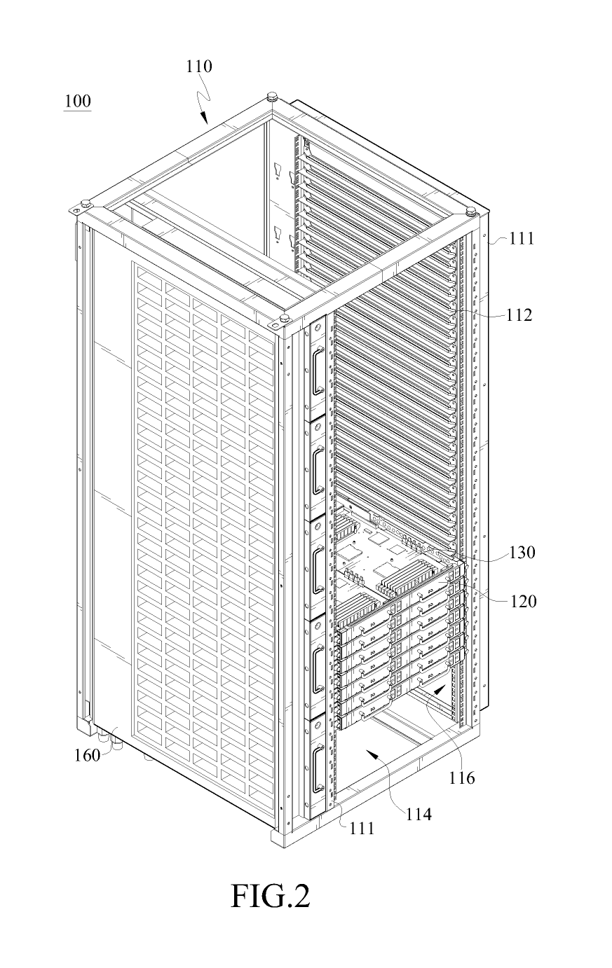

FIGS. 1 and 2 are schematic three-dimensional views according to an embodiment of the present invention. As shown in the FIGS. 1 and 2, a server cabinet 100 of the present invention comprises a rack 110, a tray 120, at least one circuit board 130, at least one fixing component 140 and at least one fan module 150. The rack 110 is a hollow rack constituted by multiple steel bars, steel plates and angle steel, so as to form an accommodation room inside the rack 110. Two opposite side surfaces of the rack 110 respectively have two opposite frame bars 111 and at least two guide rails 112. Two opposite side surfaces of the rack 110 are hollowed out to form large-area air inlets/outlets for an airflow of the fan module 150. In addition, one side of the rack 110 is opened with an opening 114, and the opening 114 is in communication with the accommodation room, so that the inside of the rack 110 is in communication with the outside through the opening 114.

The guide rails 112 of the present invention are disposed on the frame bars 111 respectively, and protrude inwards from the frame bars 111 respectively. The guide rails 112 on the two frame bars 111 are arranged symmetrically. One of the side surfaces of the rack 110 is further disposed with at least one assembling frame 115, the assembling frame 115 is located in the accommodation room of the rack 110, and one side of the rack 110 opposite to the assembling frame 115 is opened with an air outlet 116.

The fan module 150 is mounted inside the assembling frame 115 of the rack 110 laterally, so that the fan module 150 is held on the rack 110 and remains the mounting position unchanged, and thus the fan module 150 can steadily blow an airflow towards the air outlet 116.

It should be noted that, the number of the guide rails 112 of the rack 110 is multiple, and the multiple guide rails 112 on the frame bars 111 are disposed at intervals, so that an in-between accommodation room is formed between two adjacent guide rails 112. The height of the in-between accommodation room matches the height of the tray 120 exactly. Additionally, in the present invention, the number of the fan modules 150 and the number of the assembling frames 115 of the rack 110 are also multiple. The numbers of the components of the above server cabinet 100 are corresponding to each other, and those skilled in the art may adjust the numbers according to the practical requirements, which is not limited to the embodiments disclosed in the present invention.

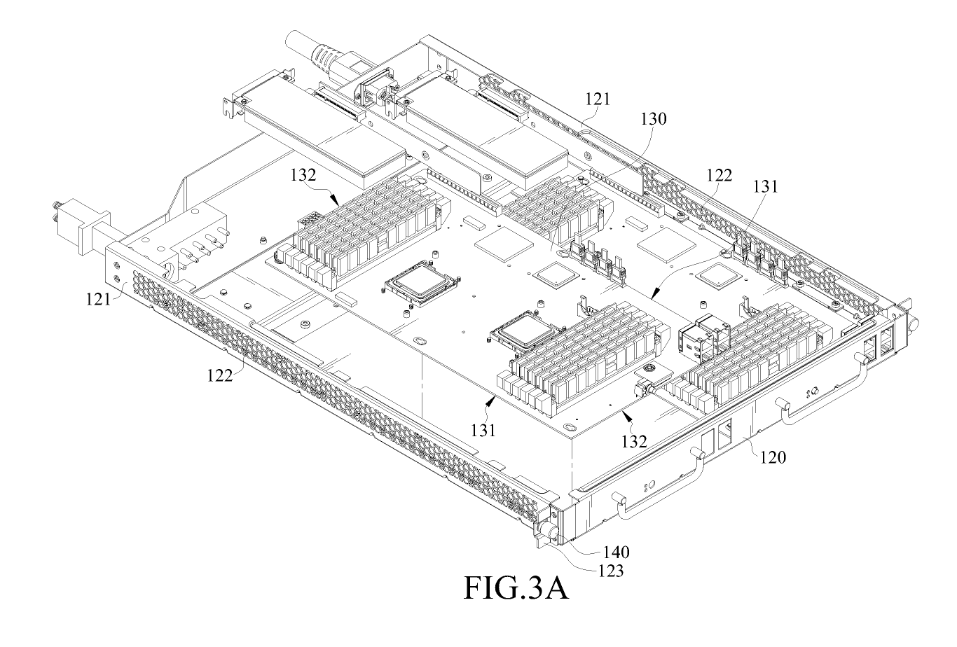

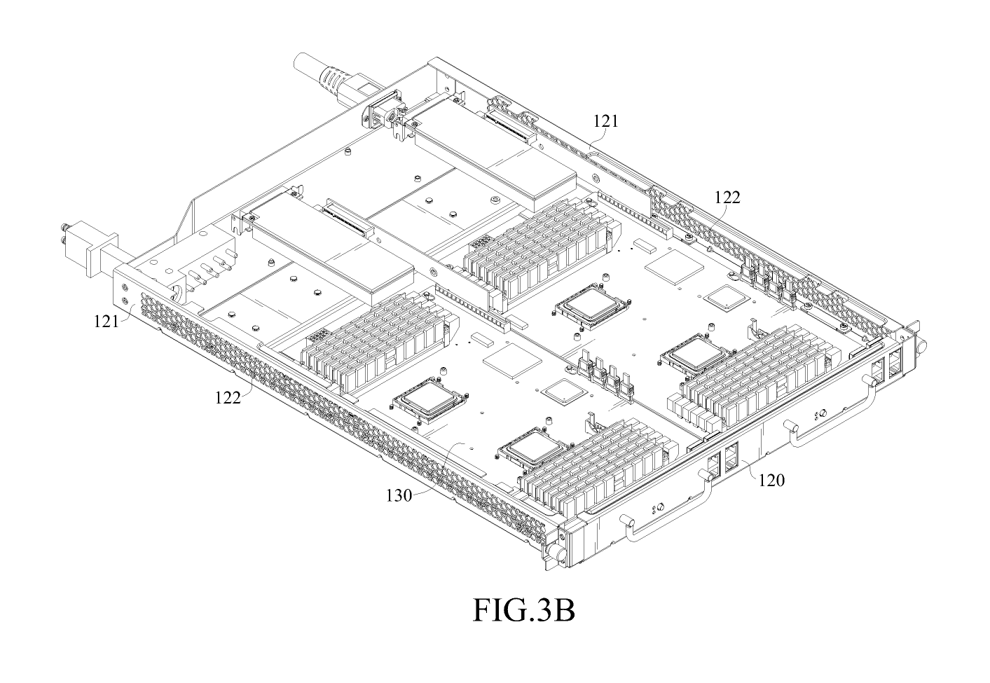

As shown in FIGS. 1 to 3B, the tray 120 of the present invention may be made of metal, and the circuit board 130 is placed on the tray 120. The circuit board 130 passes through the opening 114 from the lateral direction of the rack 110 along with the tray 120 to be loaded on the two guide rails 112, and then slides into the accommodation room of the rack 110.

Specifically, the tray 120 has two opposite side walls 121, and the side walls 121 are further opened with through holes 122. The tray 120 further has two stop plates 123 disposed on the two side walls 121 of the tray 120 respectively. The stop plates 123 are substantially perpendicular to the side walls 121. The stop plates 123 function as the peripheral architecture of the tray 120.

In this embodiment, the stop plates 123 and the tray 120 may be integrally formed, or the stop plates 123 may be additionally mounted on the tray 120, and the present invention is not limited thereto. Additionally, the number of the stop plates 123 in the present invention is two, and the stop plates 123 are symmetrically disposed on the tray 120, so as to achieve a force balance. However, those skilled in the art may simply achieve the retention affect by only disposing a single stop plate 123 on one of the side walls 121 of the tray 120, which is not limited to this embodiment.

The circuit board 130 has two opposite long side edges 131 and two opposite short side edges 132, thus forming a rectangular board structure. When the circuit board 130 is loaded on the tray 120, the long side edges 131 of the circuit board 130 are parallel to the side walls 121 of the tray 120, and the short side edges 132 of the circuit board 130 are parallel to the stop plates 123 of the tray 120.

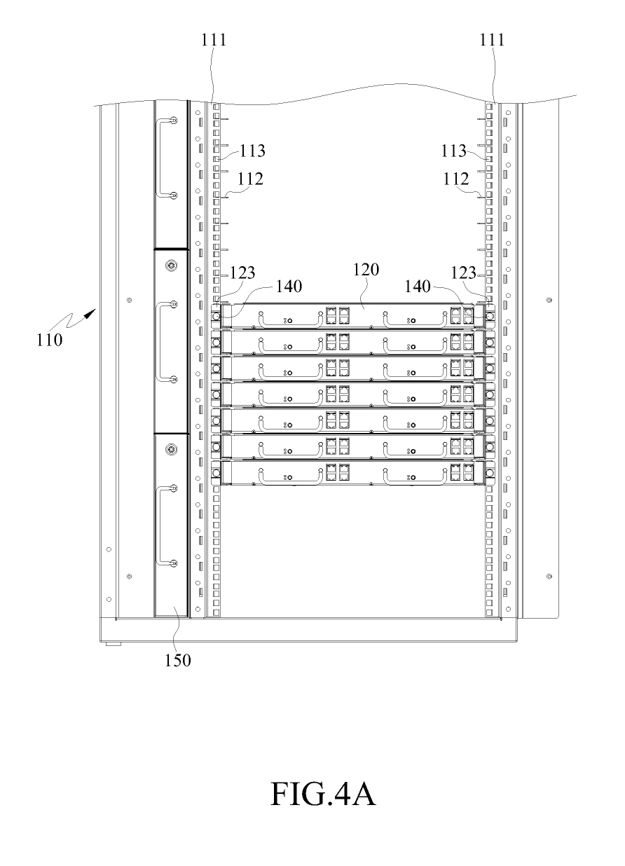

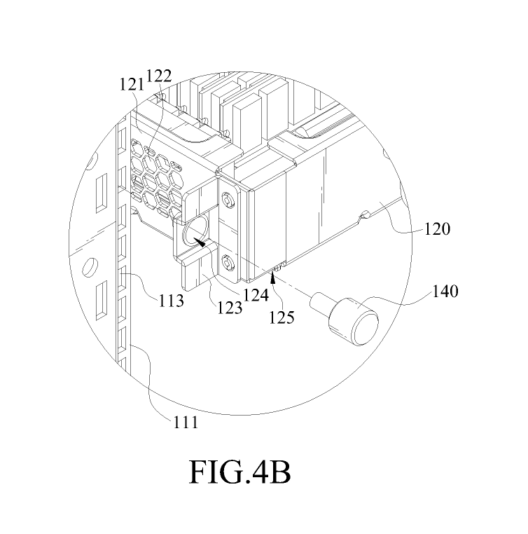

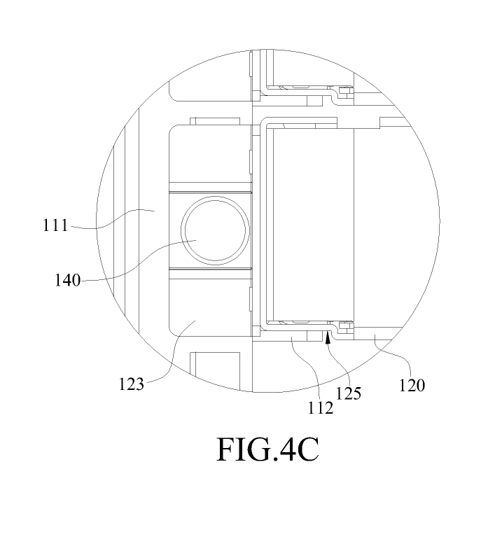

As shown in FIGS. 4A to 4C as well as FIGS. 1 and 2, the stop plates 123 of the tray 120 protrude from the tray 120 slightly, so that the length of the room occupied by the stop plates 123 is larger than the distance between the two frame bars 111 of the rack 110. The stop plate 123 is opened with at least one combining hole 124, and the combining hole 124 is corresponding to an assembly hole 113 of the frame bar 111. In addition, two symmetrical recessed portions 125 are further disposed at edges of the bottom of the tray 120, and the size and direction of the recessed portions 125 match the guide rails 112.

When the tray 120 slides into the rack 110, the tray 120 is located in an in-between accommodation room formed by two adjacent guide rails 112, and relative positions of the stop plates 123 overlap relative positions of the frame bars 111, so that the stop plates 123 press against the two frame bars 111. At this time, the combining hole 124 of the stop plate 123 is aligned to the assembly hole 113 on the frame bar 111, and the guide rails 112 are completely submerged in the recessed portions 125 of the tray 120, so that the bottom of the tray 120 and the bottom of the guide rails 112 are in the same plane, thus greatly reducing the usable room in the rack 110 occupied by the guide rails 112, and achieving the most efficient utilization of the inner room of the rack 110.

The fixing component 140, such as a pin, passes through the combining hole 124 of the stop plate 123 and the assembly hole 113 on the frame bar 111, and is inserted into the frame bar 111, so that the tray 120 is limited by the fixing component 140 and thus kept in the rack 110. In this embodiment, the fixing component 140 is a pin, but those skilled in the art may also select any fixing component other than those for screw fixation, which is not limited to the implementation of this embodiment.

Referring to FIGS. 1 and 2, the fan module 150 is connected to and driven by an external power supply device, and the fan module 150 generates an airflow and blows the airflow towards the side surface of the rack 110 opened with the opening 114. Therefore, the airflow of the fan module 150 first passes through the through holes 122 on the side wall 121 of the tray 120 to the circuit board 130, and dissipates heat of the circuit board 130 by convection. Then, the airflow flows across the short side edges 132 of the circuit board 130, and is blown to the outside of the rack 110 through the air outlet 116 of the rack 110.

The server cabinet 100 of the present invention further comprises at least one radiator 160, mounted on the side surface of the rack 110 having the fan module 150, and located outside the rack 110. In the present invention, the radiator 160 and the fan module 150 are disposed close to each other, and the radiator 160 is located at an air inlet end of the fan module 150, so that the radiator 160 can effectively lower the temperature of the air at the air inlet end of the fan module 150, thus preventing the temperature of the airflow blown into the rack 110 from being too high. The number of the radiator 160 of the present invention may be multiple, so as to provide an optimal heat dissipation effect to the server cabinet 100.

In the present invention, the fixing component is fixed in the frame bar by insertion, so that the tray can be fixedly disposed into the rack or removed from the rack quickly and conveniently, and compared with the prior art, the present invention does not need to use screws for screw fixation as the fixing components, which not only greatly simplifies the procedures for loading and unloading the tray, but also reduces the time required for the loading and unloading operation.

Additionally, the guide rails of the rack are completely accommodated in the recessed portions of the tray, and the guide rails do not protrude from the tray, but instead, are in the same plane as the tray. Since the guide rails do not occupy any other usable room inside the rack, the most efficient utilization of the usable room of the rack can be achieved, the rack can be loaded with the maximum number of circuit boards, and a single server cabinet can achieve the highest operation performance.

What is claimed is:

1. A server cabinet structure, comprising:
a rack, having an accommodation room inside and having two opposite frame bars and at least two guide rails, wherein the two frame bars respectively have a plurality of assembly holes, the two guide rails are respectively disposed on the two frame bars, and the two guide rails are arranged corresponding to each other;
at least one tray, disposed on the two guide rails, wherein the tray slides into the rack through the two guide rails, the tray has at least one stop plate and two recessed portions, the stop plate has at least one combining hole, the two recessed portions are respectively corresponding to the two guide rails, and when the tray is located in the rack, the two guide rails are respectively accommodated in the two recessed portions, the stop plate presses against one of the frame bars, and the combining hole is corresponding to one of the assembly holes of the frame bar; and
at least one fixing component, passing through the combining hole and at least one of the assembly holes, inserted into at least one of the frame bars, so as to limit and keep the tray inside the rack.

2. The server cabinet structure according to claim 1, wherein the rack is further opened with an opening in communication with the accommodation room, so that the tray passes through the opening to be mounted in the rack.

3. The server cabinet structure according to claim 1, wherein the tray has two stop plates and two fixing components, the stop plates respectively press against the two frame bars, the stop plates respectively have at least one combining hole respectively corresponding to one of the assembly holes of the two frame bars, the fixing components respectively pass through the two combining holes and at least one of the assembly holes, and the fixing components are respectively inserted into the two frame bars.

4. The server cabinet structure according to claim 1, wherein the rack has a plurality of guide rails symmetrically arranged on the two frame bars of the rack, an in-between accommodation room is formed by two adjacent guide rails, and the tray is located between the two adjacent guide rails.

5. The server cabinet structure according to claim 1, wherein the fixing component is a pin.
